(19) United States
(12) Patent Application Publication
(10) Pub. No.: US 2012/0229194 A1
(43) Pub. Date: Sep. 13, 2012

(54) TOUCH PANEL HAVING NON-INTEGRATED AND SECURELY ATTACHED PORTIONS OF A SUBSTRATE

(75) Inventor: JANE HSU, TAOYUAN COUNTY (TW)

(73) Assignee: DERLEAD INVESTMENT LTD., TAIPEI (TW)

(21) Appl. No.: 13/239,725

(22) Filed: Sep. 22, 2011

(30) Foreign Application Priority Data
Mar. 9, 2011 (TW) 100204154

(51) Int. Cl. H03K 17/96

(52) U.S. Cl. 327/517

(57) ABSTRACT

A touch panel having non-integrated and securely attached portions of a substrate has a substrate and an extended portion. The substrate takes a regular form and has two opposite surfaces, multiple edge walls and a transparent electrode layer. The transparent electrode layer is formed on one of the opposite surfaces of the substrate. The extended portion has a thickness matching that of each edge wall and is securely attached to one of the edge walls. Accordingly, a substrate having a specific form can be formed by non-integrated parts without cutting off unnecessary material during a specific cutting process, thereby simplifying the fabrication process and saving the material cost.

### BACKGROUND OF THE INVENTION

1. Field of the Invention

The present invention relates to a touch panel, and more particularly to a touch panel having non-integrated and securely attached portions of a substrate to easily meet a customized shape demand of the touch panel and save material used in the fabrication process.

2. Description of the Related Art

Touch panels having highest market share now can be classified into resistive touch panels and capacitive touch panels as far as the operation principle is concerned. According to the number of driving lines, the resistive touch panels include 4-wire, 5-wire, 6-wire and 8-wire touch panels. The capacitive touch panels include surface capacitive touch panels and projected capacitive touch panels.

Each of the foregoing touch panels has at least one substrate. The substrate is transparent and has two opposite surfaces. At least one of the surfaces has a transparent electrode layer made of indium tin oxide (ITO) and formed thereon. The operation principle of a capacitive touch panel lies in the generation of capacitance between a finger and the transparent electrode layer when the finger approaches the transparent electrode layer, so that overall capacitance of the transparent electrode layer varies. Hence, when a finger approaches a capacitive touch panel, the capacitance of corresponding coordinates of the approached position varies. Once the varied capacitance of the coordinates of a position of the transparent electrode layer is detected, the position having the varied capacitance is determined to be the position touched by the finger.

After the touch panel technologies prevail, many electronic products employ touch panels as the input interfaces. The contours of all earlier touch panels are mainly rectangular. In response to customized contour requirements of touch panels made by different electronic product manufacturers, such as the requirement that a portion of a substrate is formed on and protrudes from one side of the substrate, the original simple cutting process of substrate needs to be replaced by special cutting process. With reference to FIGS. 7A and 7B, multiple rectangular substrates 100 are cut, a main substrate portion 101 and an extended portion 102 are marked out on each substrate 100, and the portion external to both ends of the extended portion 102 is cut out to form a substrate having an extended edge.

However, to form the substrate having an extended portion, additional cutting steps and time must be required, and the removed material also causes material waste.

### SUMMARY OF THE INVENTION

An objective of the present invention is to provide a touch panel having non-integrated and securely attached portions of a substrate to easily meet a customized shape demand of the touch panel and save material used in a fabrication process.

To achieve the foregoing objective, the touch panel has a substrate and an extended portion.

The substrate takes a regular form and has a thickness, multiple edge walls, two opposite surfaces and at least one transparent electrode layer.

Each edge wall has a length. The at least one transparent electrode layer is respectively formed on at least one of the opposite surfaces.

The extended portion has a length, a thickness and an inward surface. The thickness matches that of the substrate. The inward surface is formed along a direction of the thickness of the extended portion and is securely attached to one of the edge walls of the substrate.

The touch panel having non-integrated and securely attached portions of a substrate allows the extended portion of a substrate, which is separated from the substrate, to be securely attached to one of the edge walls of the substrate so as to meet a special form requirement. The substrate itself takes a regular form and is formed without requiring specific cutting process, and the extended portion can be bonded to the substrate with simple bonding technique, thereby not only simplifying fabrication process but also saving material cost.

Other objectives, advantages and novel features of the invention will become more apparent from the following detailed description when taken in conjunction with the accompanying drawings.

### BRIEF DESCRIPTION OF THE DRAWINGS

FIG. 1 is a top view of a substrate having non-integrated and securely attached portions in accordance with the present invention;

FIG. 2 is another top view of the substrate in FIG. 1;

FIG. 3 is a cross-sectional side view of a touch panel having the substrate in FIG. 1;

FIG. 4 is a perspective view of a first embodiment of a touch panel in accordance with the present invention;

FIG. 5 is a top view of a second embodiment of a touch panel in accordance with the present invention;

FIG. 6 is a perspective view of a third embodiment of a touch panel in accordance with the present invention;

FIG. 7A is a top view of substrates of conventional touch panels in a fabrication process; and

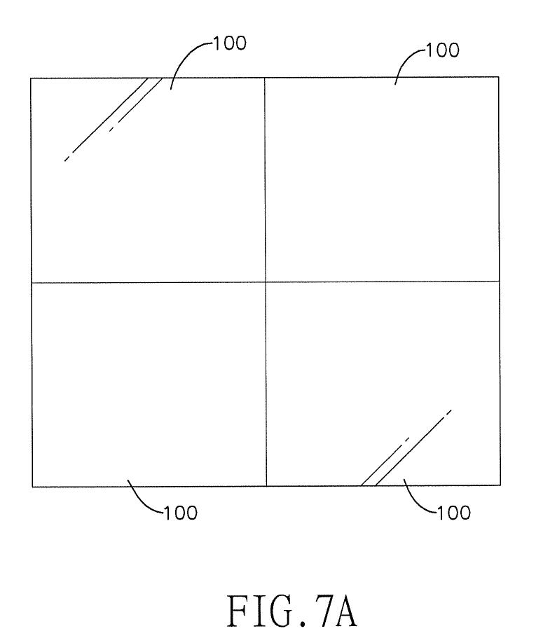

FIG. 7B is another top view of the substrate in FIG. 7A in another fabrication process.

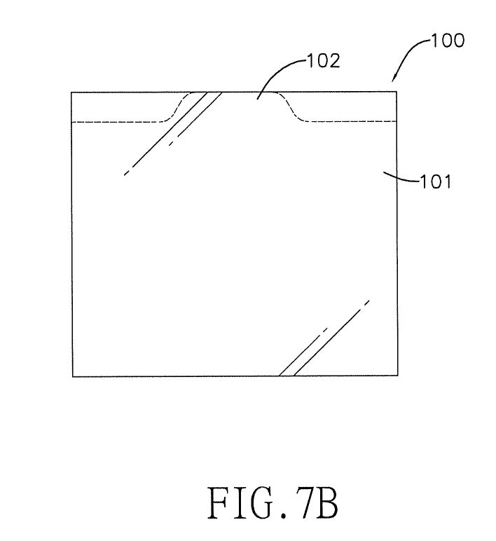

### DETAILED DESCRIPTION OF THE INVENTION

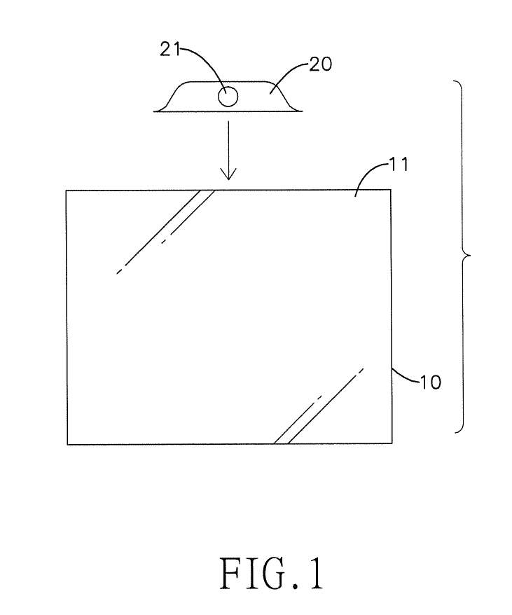

With reference to FIG. 1, a touch panel having non-integrated and securely attached portions of a substrate in accordance with the present invention has a substrate 10 and an extended portion 20 separated from and securely attached to the substrate 10.

The substrate 10 takes a regular form and has two opposite surfaces and at least one transparent electrode layer 11. The at least one transparent electrode layer 11 is respectively formed on at least one of the opposite surfaces. It means that the at least one transparent layer 11 may be formed on one of the opposite surfaces or each one of the at least one transparent layer 11 may be formed on one of the opposite surfaces. In application, two substrates 10 may commonly constitute a touch panel. Detailed description follows later. The substrate 10 has multiple edge walls. In the present embodiment the substrate 10 is rectangular and has four edge walls with each two opposite edge walls in parallel.

The extended portion 20 has a thickness matching that of the substrate 10. The extended portion 20 has an inward surface of the substrate 10. The inward surface of the extended portion 20 is formed along a direction of the thickness of the extended portion 20 and is securely attached to one of the edge walls. In the present embodiment, a length of the extended portion 20 is less than that of each edge wall, the extended portion 20 has a through hole 21 for fixing or mounting the touch panel, and the extended portion 20 is bonded to the substrate 10 by adhesive.

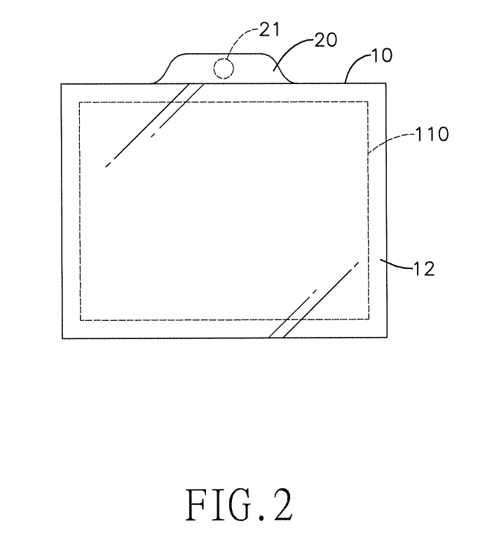

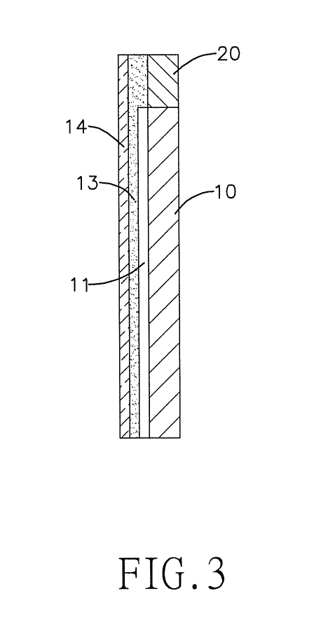

With reference to FIGS. 2 and 3, after the transparent electrode layer 11 on the substrate 10 is etched to form a sensing layer 110, the substrate 10 further has a wiring zone 12, wires, an ink layer 13 and a hardening layer 14. The wiring zone 12 is perimetrically formed on the same surface where the sensing layer 110 is formed. The wires are formed within the wiring zone 12 to connect with the sensing layer. The ink layer 13 is formed on the wiring zone 12 and simultaneously covers the extended portion 20. The hardening layer 14 is further formed on the ink layer 13.

The aforementioned touch panel is applicable to resistive touch panels and capacitive touch panels such as surface capacitive touch panels, projected touch panels and the like.

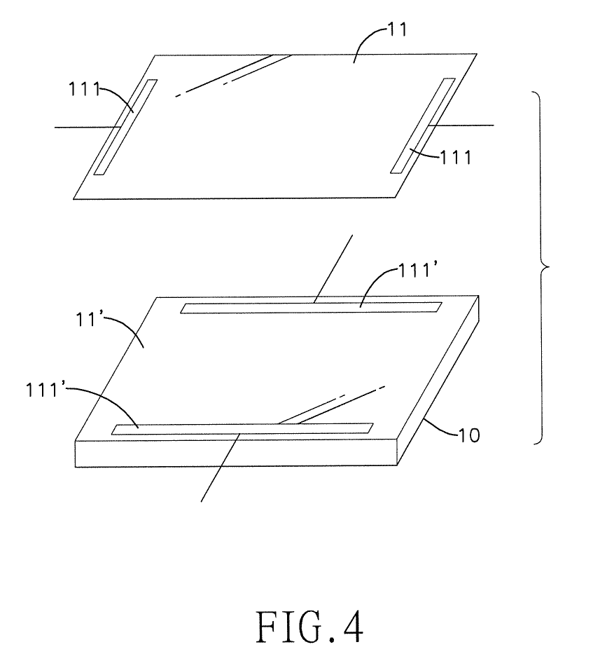

With reference to FIG. 4, a first embodiment of a touch panel in accordance with the present invention is applied to a resistive touch panel and has a substrate 10, two transparent electrode layers 11, 11′ and multiple spacers. The two transparent electrode layers 11, 11′ are formed on one surface of the substrate 10. The spacers are mounted between the transparent electrode layers 11, 11′ to isolate the transparent electrode layers 11, 11′ from each other. One of the transparent electrode layers 11 has two X-axis driving lines 111 respectively formed on two opposite ends of the transparent electrode layer 11 and being parallel to each other. The other one of the transparent electrode layers 11′ has two Y-axis driving lines 111′ respectively formed on two opposite ends of the transparent electrode layer 11′ and being parallel to each other and perpendicular to the X-axis driving lines 111. Due to the existence of four driving lines, such resistive touch panel is called 4-wire resistive touch panel. In addition, such design can be applied to five-wire and 8-wire resistive touch panels.

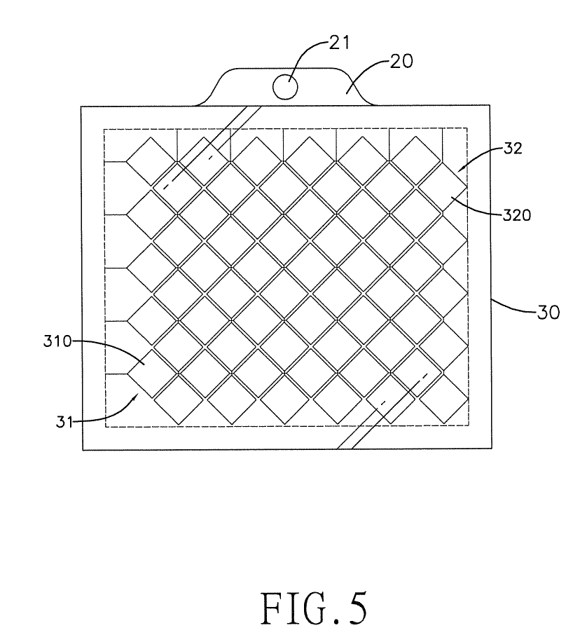

With reference to FIG. 5, a second embodiment of a touch panel in accordance with the present invention is applied to a projected capacitive touch panel and has a substrate 30, an X-axis sensing layer 31 and a Y-axis sensing layer 32. The substrate 30 has a transparent electrode layer and an extended portion 20. The transparent electrode layer is formed on one surface of the substrate and constitutes an X-axis sensing layer 31 and a Y-axis sensing layer 32. The X-axis sensing layer 31 has multiple X-axis electrodes 310 serially connected in rows. The Y-axis sensing layer 32 has multiple Y-axis electrodes 320 serially connected in columns. The rows of X-axis electrodes 310 perpendicularly align with the columns of Y-axis electrodes 320. Besides being formed on one surface of the substrate 30, the X-axis sensing layer 31 and the Y-axis sensing layer 32 may be respectively formed on the two opposite surfaces of the substrate 30. The extended portion 20 is separated from the substrate 30 and securely attached to one edge wall of the substrate 30.

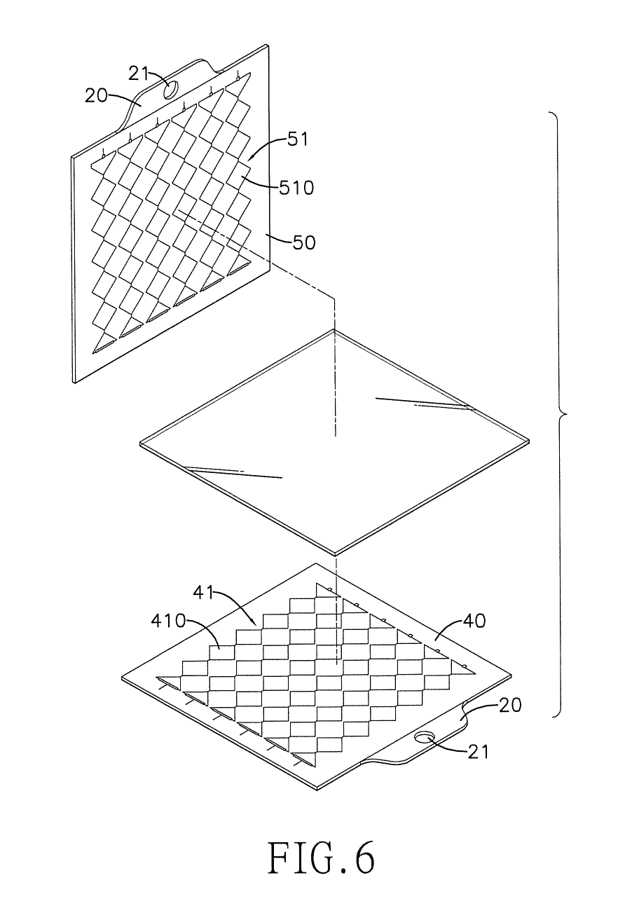

The touch panel of the present invention can be applicable not only to single-substrate projected capacitive touch panel but also to double-substrate capacitive touch panel. With reference to FIG. 6, a third embodiment of a touch panel in accordance with the present invention has two substrates 40, 50. The two substrates 40, 50 respectively have two transparent electrode layers. Each transparent electrode layer is formed on one surface of a corresponding substrate 40, 50. The two transparent electrode layers respectively constitute an X-axis sensing layer 41 and a Y-axis sensing layer 51. The X-axis sensing layer 41 has multiple X-axis electrodes 410 serially connected in rows. The Y-axis sensing layer 51 has multiple Y-axis electrodes 510 serially connected in columns. After the two substrates 40, 50 are insulatedly overlapped, the rows of X-axis electrodes 410 perpendicularly align with the columns of Y-axis electrodes 510. Each one of the two substrates 40, 50 has an extended portion 20 separated from the substrate 40, 50 and securely attached to one edge wall of the substrate 40, 50.

Besides the projected capacitive touch panels, the present invention is also applicable to surface capacitive touch panels and is characterized by formation of transparent electrode layers on one surface or two surfaces of a substrate.

When the present invention is fabricated, the substrate 10, 30, 40, 50 is cut to be rectangular, and the extended portion 20 is securely attached to one edge wall of the substrate 10, 30, 40, 50. As the extend portion 20 is securely attached to the substrate 10, 30, 40, 50 by simple bonding technique instead of being formed by cutting out unnecessary portion of the substrate 10, 30, 40, 50, not only can the material cost be saved, but also the fabrication cost can be saved because of simpler fabrication process.

Moreover, as the substrate 10, 30, 40, 50 has multiple wires formed on the wiring zone 12 of the substrate 10, 30, 40, 50 and electrically connected with the sensing layers, the touch panel of the present invention has the ink layer 13 formed on the wiring zone 12 and simultaneously covering the wires on the wiring zone and the bonding traces between the extended portion 20 and the substrate 10, 30, 40, 50. Accordingly, there is no difference between the substrate of the present invention and an integrally formed substrate in terms of exterior look.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A touch panel having non-integrated and securely attached portions of a substrate, comprising:
a substrate taking a regular form and having:
a thickness;
multiple edge walls, each edge wall having a length;
two opposite surfaces; and
at least one transparent electrode layer, the at least one transparent electrode layer respectively formed on at least one of the opposite surfaces; and
an extended portion having:
a length;
a thickness matching that of the substrate; and
an inward surface formed along a direction of the thickness of the extended portion and securely attached to one of the edge walls of the substrate.

2. The touch panel as claimed in claim 1, wherein each one of the at least one transparent electrode layer has:
a sensing layer formed on the transparent electrode layer;
a wiring zone perimetrically formed on the sensing layer; and
wires formed within the wiring zone to connect with the sensing layer.

3. The touch panel as claimed in claim 2, wherein each one of the at least one transparent electrode layer further has:
an ink layer formed on the wiring zone and simultaneously covering the extended portion; and
a hardening layer formed on the ink layer.

4. The touch panel as claimed in claim 3, wherein the inward surface of the extended portion is bonded to one of the edge walls of the substrate by adhesive.

5. The touch panel as claimed in claim 4, wherein
the length of the extended portion is less than that of each edge wall; and
the extended portion has a through hole formed therethrough.

6. The touch panel as claimed in claim 1, wherein the substrate has:
two transparent electrode layers formed on one of the opposite surfaces of the substrate;
multiple spacers formed between the two transparent electrode layers to isolate the transparent electrode layers from each other;
two X-axis driving lines respectively formed on two opposite ends of one of the transparent electrode layers; and
two Y-axis driving lines respectively formed on two opposite ends of the other one of transparent electrode layers, and being parallel to each other and perpendicular to the X-axis driving lines.

7. The touch panel as claimed in claim 1, wherein the substrate has a transparent electrode layer formed on one of the opposite surfaces of the substrate and constituting an X-axis sensing layer and a Y-axis sensing layer, the X-axis sensing layer has multiple X-axis electrodes serially connected in rows, the Y-axis sensing layer has multiple Y-axis electrodes serially connected in columns, and the rows of X-axis electrodes perpendicularly align with the columns of Y-axis electrodes.

8. The touch panel as claimed in claim 1, wherein the substrate has two transparent electrode layers respectively formed on the opposite surfaces of the substrate and respectively constituting an X-axis sensing layer and a Y-axis sensing layer, the X-axis sensing layer has multiple X-axis electrodes serially connected in rows, the Y-axis sensing layer has multiple Y-axis electrodes serially connected in columns, and the rows of X-axis electrodes perpendicularly align with the columns of Y-axis electrodes.

9. The touch panel as claimed in claim 1, wherein the panel is a surface capacitive touch panel and has a transparent electrode layer formed on one of the opposite surfaces of the substrate.

10. The touch panel as claimed in claim 1, wherein the panel is a surface capacitive touch panel and has two transparent electrode layers respectively formed on the opposite surfaces of the substrate.

11. A touch panel having non-integrated and securely attached portions of a substrate, comprising:
a first substrate having:
a thickness;
multiple edge walls, each edge wall having a length;
two opposite surfaces; and
a transparent electrode layer formed on one of the opposite surfaces and constituting an X-axis sensing layer having multiple X-axis electrodes serially connected in rows;
a second substrate having:
a thickness;
multiple edge walls, each edge wall having a length;
two opposite surfaces; and
a transparent electrode layer formed on one of the opposite surfaces and constituting a Y-axis sensing layer having multiple Y-axis electrodes serially connected in columns, wherein the rows of X-axis electrodes perpendicularly align with the columns of Y-axis electrodes after the first substrate and the second substrate are insulatedly overlapped;
two extended portions, each having:
a length;
a thickness matching that of one of the substrates; and
an inward surface formed along a direction of the thickness of the extended portion and securely attached to one of the edge walls of the corresponding substrate.
